(19) United States
(12) Patent Application Publication
(10) Pub. No.: US 2012/0309155 A1
(43) Pub. Date: Dec. 6, 2012

(54) SEMICONDUCTOR PROCESS

(75) Inventors: Wen-Chieh Wang, Taoyuan County (TW); Yi-Nan Chen, Taipei City (TW); Hsien-Wen Liu, Taoyuan County (TW)

(73) Assignee: NANYA TECHNOLOGY CORPORATION, Taoyuan (TW)

(21) Appl. No.: 13/152,283

(22) Filed: Jun. 3, 2011

(51) Int. Cl. H01L 21/8239

(52) U.S. Cl. 438/294; 257/E21.645

(57) ABSTRACT

A semiconductor process is provided. A substrate is provided, gates each including a silicon layer, a silicide layer and a cap layer are formed thereon, and doped regions are formed at two sides of each gate. An insulating layer is formed to cover a memory region and a periphery region. First contact holes are formed in the insulating layer in the memory region, and each first contact hole is disposed between the two adjacent gates and exposes the doped region. A contact plug is formed in each first contact hole to electrically connect the doped region. A patterned mask layer is formed on the substrate to cover the memory region and expose a portion of the periphery region. Using the patterned mask layer as a mask, second and third contact holes are formed in the insulating layer in the periphery region, to expose the silicide layer and the doped region.

### BACKGROUND OF THE INVENTION

1. Field of the Invention

The invention relates to a semiconductor process.

2. Description of Related Art

In the semiconductor process, in order to reduce number of photomasks, one photomask is used to simultaneously defined a plurality of contact holes in the insulating layer, including the contact holes disposed between the bit lines, the contact holes exposing the gates in the periphery region, and the contact holes exposing the source and drain regions in the periphery region. However, when an etching process is applied to form these contact holes simultaneously, over-etching or under-etching of the layers may be occurred because the material and the thickness of the layers required to be removed are not identical. As such, electrical connection between the contact plugs formed in the contact holes and the devices is negatively affected, and the characteristics of the semiconductor device are deteriorated. Otherwise, if the contact holes are defined respectively by different photomasks, the fabrication cost and the processing time are increased.

### SUMMARY OF THE INVENTION

The invention is directed to a semiconductor process, which forms the contact holes with desired profiles and reduces the fabrication cost and the processing time of the semiconductor device.

The invention provides a semiconductor process. A substrate is provided, wherein the substrate includes a memory region and a periphery region, a plurality of gates is formed on the substrate, doped regions are formed at two sides of each gate, and each gate includes a silicon layer, a silicide layer and a cap layer sequentially formed on the substrate. An insulating layer is formed on the substrate to cover the memory region and the periphery region. A plurality of first contact holes is formed in the insulating layer in the memory region, and each first contact hole is disposed between the two adjacent gates and exposes one of the doped regions in the memory region. A contact plug is formed in each first contact hole to electrically connect the doped region. A patterned mask layer is formed on the substrate to cover the memory region and to expose a portion of the periphery region. By using the patterned mask layer as a mask, a plurality of second contact holes and third contact holes are simultaneously formed in the insulating layer in the periphery region, wherein each second contact hole exposes the silicide layer of one of the gates in the periphery region, and each third contact hole exposes one of the doped regions in the periphery region. Second and third contact plugs are formed in the second and third contact holes, so as to electrically connect to the silicide layer and the doped region, respectively.

According to an embodiment of the invention, a method of forming the first contact holes includes the following steps. A plurality of primary contact holes is formed in the insulating layer in the memory region, wherein each primary contact hole is disposed between the two adjacent gates and exposes one of the doped regions in the memory region. A sacrificial layer is formed on the insulating layer, wherein the sacrificial layer is filled in each primary contact hole. A planarization process is performed on the sacrificial layer and the insulating layer, so as to remove the sacrificial layer outside the primary contact holes. The sacrificial layer in the primary contact holes is removed to form the first contact holes.

According to an embodiment of the invention, a material of the sacrificial layer includes polysilicon.

According to an embodiment of the invention, a method of forming the first contact plugs includes the following steps. A first conductive layer is formed on the insulating layer, wherein the first conductive layer is filled in each first contact hole. A planarization process is performed on the first conductive layer, so as to remove the first conductive layer outside the first contact holes and to form the first contact plug in each first contact hole.

According to an embodiment of the invention, a material of the first conductive layer includes tungsten.

According to an embodiment of the invention, a material of the insulating layer includes borophosilicate glass (BPSG).

According to an embodiment of the invention, further includes a gate dielectric layer disposed on a surface of each gate and between each gate and the substrate.

According to an embodiment of the invention, the step of forming each first contact hole further includes removing a portion of the gate dielectric layer on the cap layer.

According to an embodiment, of the invention, a method of forming the second and third contact holes includes performing an etching process on the insulating layer by using the patterned mask layer as a mask. In the etching process, the silicide layers are used as an etching stop layer to remove a portion of the insulating layer and a portion of the cap layers of the gates, so as to form the second contact holes, and the doped regions are used as an etching stop layer to remove another portion of the insulating layer, so as to form the third contact holes.

According to an embodiment of the invention, a material of the insulating layer includes borophosilicate glass (BPSG).

According to an embodiment of the invention, a material of the cap layers includes nitride.

According to an embodiment of the invention, a material of the doped regions includes doped silicon.

Based on the above, in the semiconductor process of the invention, the contact holes disposed in the memory region are formed by using a photomask, and the contact holes exposing the gates in the periphery region and the contact holes exposing the doped regions in the periphery region are formed simultaneously by using another photomask. As such, the contact holes have desired profiles respectively and the fabrication cost and the processing time of the semiconductor device is reduced.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A to FIG. 1F are cross-sectional views illustrating a semiconductor process according to an embodiment of the invention.

### DESCRIPTION OF EMBODIMENTS

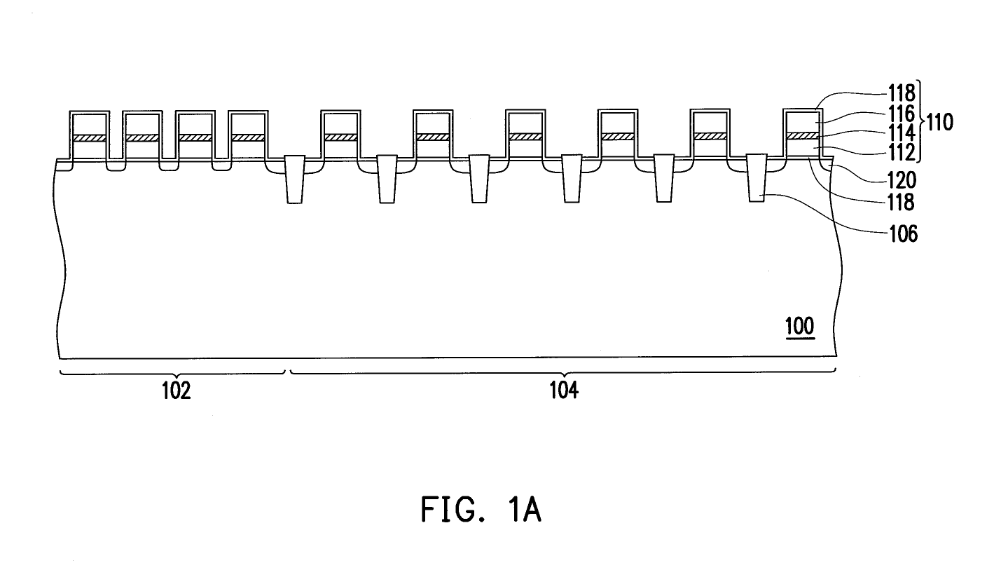

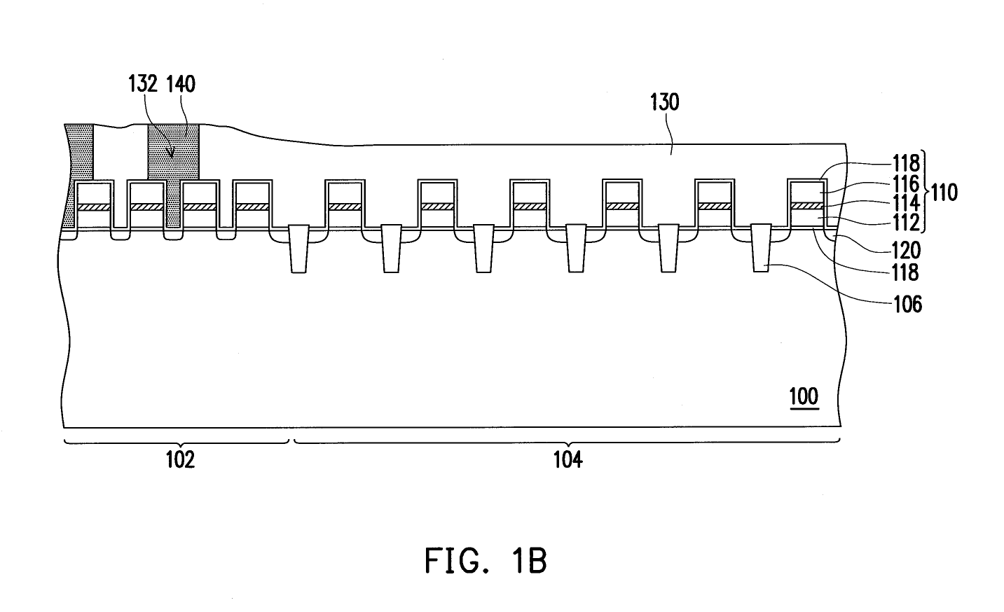

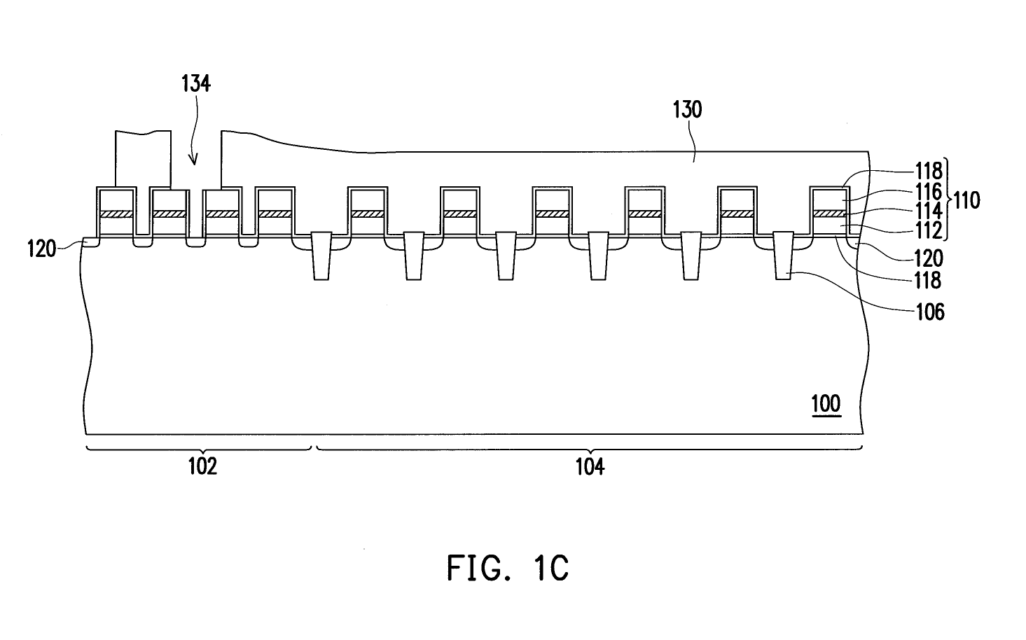

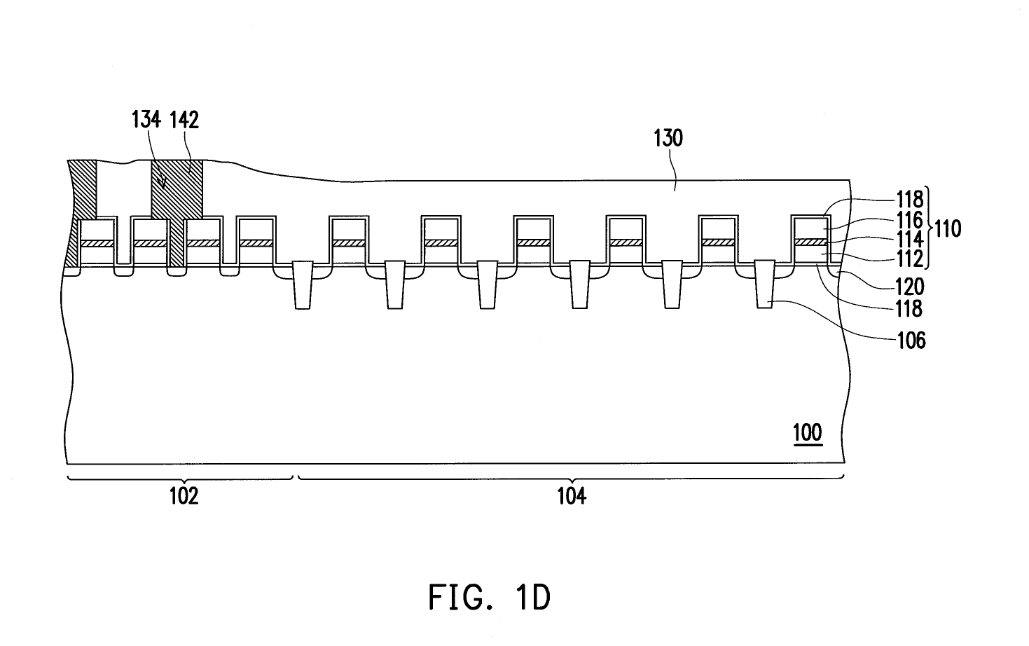

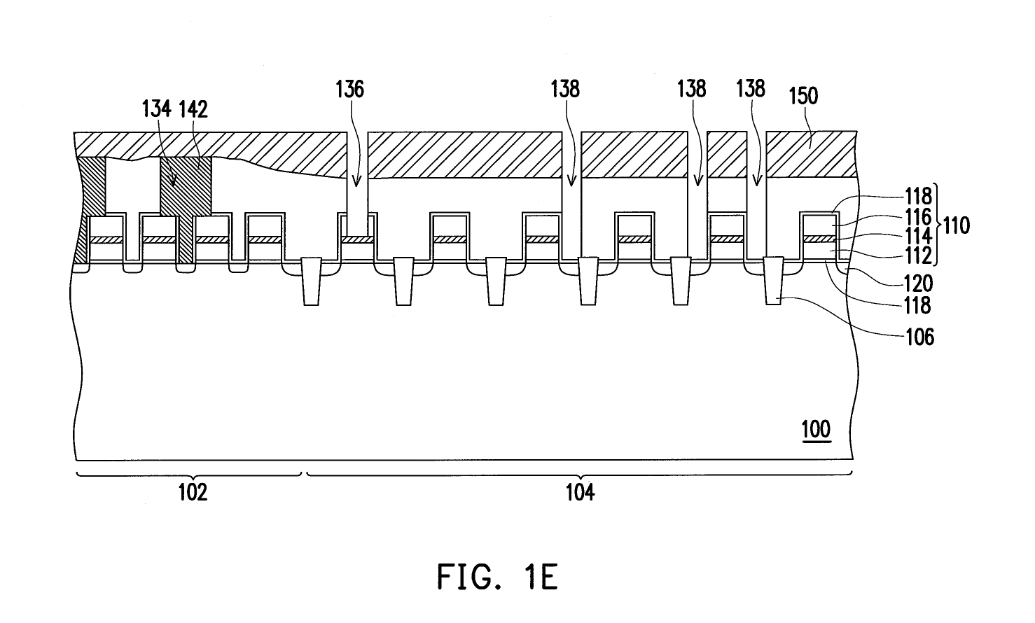

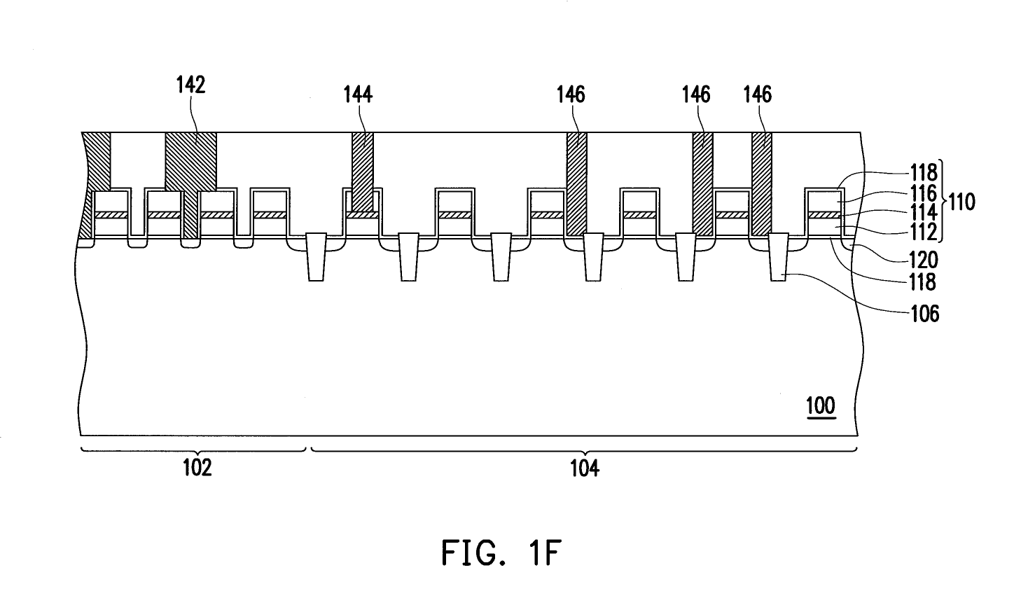

FIG. 1A to FIG. 1F are cross-sectional views illustrating a semiconductor process according to an embodiment of the invention. With reference to FIG. 1A, a substrate 100 is provided, wherein the substrate 100 includes a memory region 102 and a periphery region 104, a plurality of gates 110 is formed on the substrate 100, doped regions 120 are formed at two sides of each gate 110, and each gate 110 includes a silicon layer 112, a silicide layer 114 and a cap layer 116 sequentially formed on the substrate 100. In this embodiment, the substrate 100 is, for example, a silicon substrate, and a plurality of STI structure is formed therein. The doped regions 120 are source and drain regions, for example. In this embodiment, a material of the silicide layers 114 is, for example, WSi₂, TiSi₂, CoSi₂, NiSi₂ or any other suitable silicide material. A material of the cap layers 116 is, for example, nitride. In this embodiment, a gate dielectric layer 118 is disposed on a surface of each gate 110 and between each gate 110 and the substrate 100, and a material of the gate dielectric layer 118 is, for example, oxide.

With reference to FIG. 1B, then, an insulating layer 130 is formed on the substrate 100 to cover the memory region 102 and the periphery region 104. Next, a plurality of primary contact holes 132 is formed in the insulating layer 130 in the memory region 102, and each primary contact holes 132 is disposed between the two adjacent gates 110 and exposes one of the doped regions 120 in the memory region 102. After that, a sacrificial layer 140 is formed on the insulating layer 130, wherein the sacrificial layer 140 is filled in each primary contact hole 132. A planarization process is then performed on the sacrificial layer 140 and the insulating layer 130, so as to remove the sacrificial layer 140 outside the primary contact holes 132. In this embodiment, a material of the insulating layer 130 includes borophosilicate glass (BPSG), and a material of the sacrificial layer 140 is polysilicon, for example. The planarization process is, for example, a chemical mechanical polishing process.

With reference to FIG. 1C, afterwards, the sacrificial layer 140 in the primary contact holes 132 is removed to form the first contact holes 134. Each first contact hole 134 is disposed between the two adjacent gates 110 and exposes one of the doped regions 120 in the memory region 102. In this embodiment, the step of removing the sacrificial layer 140 in the primary contact holes 132 further includes removing a portion of the gate dielectric layer 118 on the cap layers 116. In this embodiment, each first contact hole 134 is passing through the insulating layer 130 disposed between and on the two adjacent gates 110, a portion of the gate dielectric layer 118 disposed on the cap layer 116 and the gate dielectric layer 118 disposed on the substrate 100 between the two adjacent gates 110. It is noted that in this embodiment, the first contact hole 134 is formed by using the sacrificial layer 140, so as to facilitate the planarization process on the insulating layer 130, but the invention is not limited thereto. In another embodiment, the first contact hole 134 may be directly formed in the insulating layer 130, and the steps of forming the primary contact holes 132, filling the sacrificial layer 140 in the primary contact holes 132 and removing the sacrificial layer 140 in the primary contact holes 132 are not required.

With reference to FIG. 1D, after that, a first conductive layer (not shown) is formed on the insulating layer 130, wherein the first conductive layer is filled in the first contact holes 134. Then, a planarization process is performed on the first conductive layer, so as to remove the first conductive layer outside the first contact holes 134 and to form the first contact plugs 142 in the first contact hole 134, wherein the first contact holes 134 are electrically connected to the doped regions 120. In this embodiment, a material of the first conductive layer is, for example, tungsten or other suitable conductive materials, and a method of forming the same is, for example, a chemical vapor deposition process. The planarization process can be a chemical mechanical polishing process. In one embodiment (not shown), the first contact plug 142 can be a two-layered structure which is composed by, for example, a tungsten layer and a titanium nitride layer disposed between the tungsten layer and the first contact hole 134. In this embodiment, the first contact plug 142 is configured to electrically connect to the bit line (not shown), for example, while in other embodiments the first contact plug 142 can also be configured to electrically connect to other components.

With reference to FIG. 1E, next, a patterned mask layer 150 is formed on the substrate 100 to cover the memory region 102 and to expose a portion of the periphery region 104. By using the patterned mask layer 150 as a mask, a plurality of second contact holes 136 and third contact holes 138 are simultaneously formed in the insulating layer 130 in the periphery region 104, wherein each second contact hole 136 exposes the silicide layer 114 of one of the gates 110 in the periphery region 104, and each third contact hole 138 exposes one of the doped regions 120 in the periphery region 104. In detail, by using the patterned mask layer 150 as a mask, an etching process is performed on the insulating layer 130, wherein the silicide layers 114 are used as an etching stop layer to remove a portion of the insulating layer 130 and a portion of the cap layers 112 of the gates 110, so as to form the second contact holes 136, and simultaneously, the doped regions 120 are used as an etching stop layer to remove another portion of the insulating layer 130, so as to form the third contact holes 138. In this embodiment, a material of the insulating layer 130 can be borophosilicate glass (BPSG), a material of the cap layer 116 can be nitride, and a material of the doped region 120 can be doped silicon. In this embodiment, each second contact hole 136 is passing through a portion of the gate dielectric layer 118 disposed on the cap layer 116 and a portion of the cap layer 116, and therefore the silicide layer 114 of the gate 110 is exposed. The third contact hole 138 is passing through the insulating layer 130 to expose the doped region 120. It is noted that, in this embodiment, the silicide layer 114 has a high etching selectivity related to other insulating layers including the gate dielectric layer 118, the cap layer 116 and the insulating layer 130, and the doped regions 120 has a high etching selectivity related to the insulating layer 130. Therefore, by using a single etching process, the second contact hole 136 and the third contact hole 138 which has a depth lager than that of the second contact hole 136 can be simultaneously formed in the insulating layer 130 without over-etching or under-etching. Accordingly, the second contact hole 136 and the third contact hole 138 have desired profiles respectively.

With reference to FIG. 1F, second contact plug 144 and third contact plug 146 are formed in the second contact hole 136 and third contact hole 138, so as to electrically connect to the silicide layer 114 and the doped region 120, respectively. In this embodiment, a method of forming the second contact plug 144 and the third contact plug 146 includes the following steps. A second conductive layer (not shown) is formed on the substrate 100 to fill the second contact holes 136 and third contact holes 138. Then, the second conductive layer outside the second contact holes 136 and third contact holes 138 is removed to form the second contact plug 144 and the third contact plug 146. Note that in this embodiment, the second contact plug 144 and third contact plug 146 are formed by the same photolithographic process, and thus the semiconductor process is simplified and the fabrication cost is reduced. Besides, in other embodiments (not shown), the second conductive layer forming the second contact holes 136 and third contact holes 138 can further cover the first contact plug 142, and then the second conductive layer can be further patterned to form a conductive line (i.e. bit line) or other conductive components, thereby electrically connecting the conductive line or other conductive components to the first, second, and third contact plugs 142, 144,146.

Generally, when the contact holes are simultaneously defined by using a photomask, over-etching or under-etching of the layers may be occurred because the material and the thickness of the layers required to be removed are not identical. Thus, the profiles of the contact holes are difficult to control. In the semiconductor process of the embodiment, the first contact holes disposed in the memory region (i.e. disposed between the bit lines) are defined by using a photomask, and the second contact holes exposing the gates in the periphery region and the third contact holes exposing the doped regions in the periphery region are simultaneously defined by using another photomask. In other words, these contact holes are formed by two patterning processes, wherein the first contact holes disposed in the memory region are formed in one patterning process, and the and the second contact holes exposing the gates in the periphery region and the third contact holes exposing the doped regions in the periphery region are formed simultaneously in the other patterning process. As such, the desired profiles of the first, second and third contact holes are obtained, and the fabrication cost and the processing time of the semiconductor device are decreased.

Particularly, in the formation of the second and third contact holes, the silicide layer has a high etching selectivity related to other insulating layers including the gate dielectric layer, the cap layer and the insulating layer, and the doped regions has a high etching selectivity related to the insulating layer, and thus the silicide layer and the doped regions are simultaneously used as etching stop layers. Therefore, by using a single etching process, the second contact hole and the third contact hole which has a depth lager than that of the second contact hole can be simultaneously formed in the insulating layer without over-etching or under-etching. As such, the desired profiles of the second and third contact holes are obtained, and the fabrication cost and the processing time of the semiconductor device are decreased.

In light of the foregoing, in the semiconductor process of the invention, the contact holes disposed in the memory region are formed by using a photomask, and the contact holes exposing the gates in the periphery region and the contact holes exposing the doped regions in the periphery region are formed simultaneously by using another photomask. In other words, the contact holes disposed in the memory region are formed in one patterning process, and the and the contact holes exposing the gates in the periphery region and the contact holes exposing the doped regions in the periphery region are formed simultaneously in the other patterning process. As such, the contact holes have desired profiles and the fabrication cost and the processing time of the semiconductor device is reduced.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A semiconductor process, comprising:
providing a substrate, wherein the substrate includes a memory region and a periphery region, a plurality of gates is formed on the substrate, doped regions are formed at two sides of each gate, and each gate comprises a silicon layer, a silicide layer and a cap layer sequentially formed on the substrate;
forming an insulating layer on the substrate to cover the memory region and the periphery region;
forming a plurality of first contact holes in the insulating layer in the memory region, wherein each first contact hole is disposed between the two adjacent gates and exposes one of the doped regions in the memory region;
forming a first contact plug in each first contact hole to electrically connect the doped region;
forming a patterned mask layer on the substrate to cover the memory region and to expose a portion of the periphery region;
by using the patterned mask layer as a mask, simultaneously forming a plurality of second contact holes and third contact holes in the insulating layer in the periphery region, wherein each second contact hole exposes the silicide layer of one of the gates in the periphery region, and each third contact hole exposes one of the doped regions in the periphery region; and
forming second and third contact plugs in the second and third contact holes, so as to electrically connect to the silicide layer and the doped region, respectively.

2. The semiconductor process as claimed in claim 1, wherein a method of forming the first contact holes comprises:
forming a plurality of primary contact holes in the insulating layer in the memory region, wherein each primary contact hole is disposed between the two adjacent gates and exposes one of the doped regions in the memory region;
forming a sacrificial layer on the insulating layer, wherein the sacrificial layer is filled in each primary contact hole;
performing a planarization process on the sacrificial layer and the insulating layer, so as to remove the sacrificial layer outside the primary contact holes; and
removing the sacrificial layer in the primary contact holes to form the first contact holes.

3. The semiconductor process as claimed in claim 2, wherein a material of the sacrificial layer comprises polysilicon.

4. The semiconductor process as claimed in claim 1, wherein a method of forming the first contact plugs comprises:
forming a first conductive layer on the insulating layer, wherein the first conductive layer is filled in each first contact hole; and
performing a planarization process on the first conductive layer, so as to remove the first conductive layer outside the first contact holes and to form the first contact plug in each first contact hole.

5. The semiconductor process as claimed in claim 4, wherein a material of the first conductive layer comprises tungsten.

6. The semiconductor process as claimed in claim 1, wherein a material of the insulating layer comprises borophosilicate glass (BPSG).

7. The semiconductor process as claimed in claim 1, further comprising a gate dielectric layer disposed on a surface of each gate and between each gate and the substrate.

8. The semiconductor process as claimed in claim 7, wherein the step of forming each first contact hole further comprises removing a portion of the gate dielectric layer disposed on the cap layer.

9. The semiconductor process as claimed in claim 1, wherein a method of forming the second and third contact holes comprises:
by using the patterned mask layer as a mask, performing an etching process on the insulating layer, wherein the silicide layers are used as an etching stop layer to remove a portion of the insulating layer and a portion of the cap layers of the gates, so as to form the second contact holes, and the doped regions are used as an etching stop layer to remove another portion of the insulating layer, so as to form the third contact holes.

10. The semiconductor process as claimed in claim 9, wherein a material of the insulating layer comprises borophosilicate glass (BPSG).

11. The semiconductor process as claimed in claim 9, wherein a material of the cap layers comprises nitride.

12. The semiconductor process as claimed in claim 9, wherein a material of the doped regions comprises doped silicon.
